(19) United States
(12) Patent Application Publication
(10) Pub. No.: US 2023/0383434 A1
(43) Pub. Date: Nov. 30, 2023

(54) A Process For Producing Diamonds

(71) Applicants: Jayeshkumar Dhirajlal Mistry, Surat (IN); Abhishek Jayeshkumar Mistry, Surat (IN)

(72) Inventors: Jayeshkumar Dhirajlal Mistry, Surat (IN); Abhishek Jayeshkumar Mistry, Surat (IN)

(21) Appl. No.: 18/031,485

(22) PCT Filed: Oct. 13, 2021
(86) PCT No.: PCT/IN2021/050982

§ 371 Date: Apr. 12, 2023

(30) Foreign Application Priority Data
Oct. 13, 2020 (IN) 202021044550

(51) Int. Cl. C30B 25/10; C30B 29/04; C30B 25/12

(52) U.S. Cl. CPC C30B 25/105; C30B 29/04; C30B 25/12

(57) ABSTRACT

The invention discloses a process to produce diamonds by microwave plasma chemical vapor deposition (MPCVD). The process uses calibration gas comprising a mixture of 3% to 12% argon per unit of hydrogen, less than 1% oxygen per unit of hydrogen and less than 500 ppm nitrogen in a chamber having diamond seed(s) in an atmosphere of hydrogen plasma.

### FIELD OF THE INVENTION

One of the most common methods to obtain diamonds is mining wherein diamonds are produced naturally. However, these nature-found diamonds have their own limitations. The major problem with the mined/nature-found diamonds is inconsistency in quality i.e., they do not have the same clarity, color or size throughout the stones.

Due to the inconsistency in clarity, color and size of mined/nature-found diamonds, it becomes difficult to make high optical grade diamonds for use in scientific and various industrial purposes.

Second inconsistency is in terms of quantity. The quantity of diamonds found in the mines always vary. Furthermore, mining affects the environment as it causes destruction of earth's crust. It also causes respiratory problems to the mineworkers and the blasts can even cause fire, which may lead to loss of lives.

One of the conventionally and synthetically known process is Microwave Plasma Chemical Vapor Deposition (MPCVD) process for producing diamonds. The process involves deposition of diamond on a substrate using a simple hydrocarbon gas and hydrogen at specific temperature of about 800° C. to 1200° C.

The quality that is color, clarity and sizes of the diamonds produced by MPCVD process can be controlled as required. Thus, it becomes easy to meet the demands for industrial grade diamonds including the high optical-grade diamonds. It also helps to save the environment and to stop the health hazards caused to the workers.

However, Microwave Plasma Chemical Vapor Deposition (MPCVD) process for producing diamonds has the drawback of slow deposition rate wherein the deposition rate is approximately 1 micrometer per hour to 3 micrometers per hour. Having a lower growth-rate utilizes more time to achieve the size despite of smooth deposition of carbon atoms on the substrate.

Thus, to achieve higher deposition rate, nitrogen gas was introduced in the process. By introducing nitrogen gas in the process, the deposition rate obtained is up to 50 microns per hour or above. Having a fast growth-rate helps save time for achieving the desired size. But nitrogen gas affects the quality of the diamonds that is it gives a low color grade.

Therefore, there is a need to control the amount of gases and other parameters (such as pressure and power) of the process so that the deposition is at a medial/moderate rate in order to stabilize the deposition and yet keep the substrate temperature in the stable range without affecting the quality of the diamonds.

### SUMMARY OF THE INVENTION

An aspect of the present invention comprises of a process for producing diamonds by microwave plasma chemical vapour deposition (MPCVD). The process comprises of introducing calibration gas having a mixture of 3% to 12% argon per unit of hydrogen, less than 1% oxygen per unit of hydrogen and less than 500 ppm nitrogen in a chamber having one or more heated diamond seeds in an atmosphere of hydrogen plasma followed by adding methane gas to deposit carbon on the diamond seed.

In another aspect of the invention, calibration gas comprising a mixture of 3% to 12% argon per unit of hydrogen, less than 1% oxygen per unit of hydrogen and less than 500 ppm is disclosed.

### DESCRIPTION OF THE INVENTION

In an embodiment of the present invention, a process to produce diamonds is disclosed. Diamonds are produced by microwave plasma chemical vapour deposition (MPCVD). The process includes the step of introducing calibration gas in a chamber having one or more heated diamond seed in an atmosphere of hydrogen plasma. The calibration gas comprises of a mixture of 3% to 12% argon per unit of hydrogen, less than 1% oxygen per unit of hydrogen and less than 500 ppm nitrogen. The step of introducing calibration gas in the chamber is followed by adding methane to deposit carbon on one or more diamond seed.

In an embodiment, the calibration gas is introduced in a vacuum applied chamber.

The diamond seed(s) are placed on a holder plate in the chamber. The chamber comprises of one or more holder plates. The holder plates are preferably made of molybdenum.

In a preferred embodiment of the present invention, a process for producing diamond by microwave plasma chemical vapour deposition (MPCVD) technique is provided. The process comprises of placing a single or plurality of a substrate (diamond seed(s)) on a holder plate in a chamber followed by applying vacuum to the chamber. Further, hydrogen plasma is ignited with microwaves and passed in the chamber to heat the diamond seed(s). The hydrogen plasma is ignited using microwaves at about 1 KW and in the pressure range from about 0-5 mbar. After this both the parameters gradually ramp-up to the desired set-point. The temperature of heating is maintained in a range of 750°-900° C. The above step is followed by introducing calibration gas in the chamber. Methane is added in the chamber, which mixes with the calibration gas and carbon is deposited on the diamond seed(s) to produce or grow diamond.

A specially prepared adhesive, conductive paste is used to keep the seeds in place and improve the heat conductivity from seeds to the holder plate. This special paste comprises of a colloidal solution of special epoxy and gold.

The calibration gas comprises a mixture of 3% to 12% argon per unit of hydrogen, less than 1% oxygen per unit of hydrogen and less than 500 ppm nitrogen.

In an embodiment of the present invention, argon is present from 3% to 8% per unit of hydrogen.

In an embodiment of the present invention, oxygen is present from 0.05% to 1% per unit of hydrogen.

In an embodiment of the present invention, nitrogen is present from 5-500 ppm.

Methane is preferably added in a gaseous form in an amount of 2% to 7% per unit of hydrogen.

The vacuum is applied in the chamber with a base pressure of up to 1.0×10⁻⁵ mbar.

The pressure in the chamber is in a range of 160 mbar to 200 mbar.

In an embodiment of the present invention, a calibration gas comprises a mixture of 3% to 12% argon per unit of hydrogen, less than 1% oxygen per unit of hydrogen and less than 500 ppm nitrogen.

In an embodiment of the present invention, a calibration gas comprises argon from 3% to 8% per unit of hydrogen, oxygen from 0.05% to 1% per unit of hydrogen and nitrogen from 5-500 ppm.

In an embodiment of the invention, a process to prepare calibration gas comprises mixing argon from 3% to 8% per unit of hydrogen, oxygen from 0.05% to 1% per unit of hydrogen and less than 500 ppm of nitrogen.

The calibration gas helps in the surface curing and activating the growth surface of the diamond seed(s).

The carbon deposition process is controlled and stabilized by using calibration gas in the reaction with the other gases such as hydrogen and methane. The percentage of combination of gases used is such that the presence of impurities in the growth lattice structure of diamond is minimum or negligible.

The deposition process is carried out at a very moderate and stable rate that is neither too fast nor too slow. The growth is achieved in a very medial temperature range that does not vary vastly (Δ200° C.) that is the growth temperature is from 900° C. to 1100° C. The deposition process is carried out under a minimal range of pressure from 160 mbar to 200 mbar so as to get a consistent repetition of results.

The use of calibration gas helps to excite the plasma by exciting the movement of the atomic hydrogen (H⁺) which helps to break the C—H bonds in methane (CH₄) easily. The calibration gas helps to stabilize the deposition of carbon atoms to avoid inclusions. The percentage of combination of gases used is such that the presence of impurities in the growth lattice structure is minimum. Growing diamonds at a moderate growth-rate gives a good color to the diamonds. Having a moderate growth-rate of diamonds and the use of the calibration gas ensuring a good color and a stable deposition of carbon atoms, further lead to good clarity of diamonds.

The quality of the diamond depends on factors, like the growth-rate and temperature. The growth-rate depends on the nitrogen content in the atmosphere inside the chamber. The argon gas helps to excite the hydrogen plasma further. Since the argon atoms are bigger in size, the atomic hydrogen keeps dashing into the argon atoms and gets hyper-activated. Due to this, it becomes much easier for these hyperactive hydrogen atoms to break down the carbon atoms from the methane.

The process helps to achieve a moderate growth rate of the diamonds and the growth rate is 8-20 μm/hr. The growth rate is dependent on the amount of nitrogen and methane in the chamber. The moderate growth rate of the diamond is advantageous as diamonds with good color and clarity are obtained.

### EXAMPLES

The following examples illustrate the invention but are not limiting thereof:

### Example 1: Process to Produce Diamond

9 diamond seeds of 400 μm thickness were placed on molybdenum holder plate. The holder plate was kept in a chamber. A special adhesive paste described above was used to keep the seeds in place and to improve thermal conductivity from seeds to the plate. The heat transfer from the holder plate to the cooling stage was controlled by the method of thermal isolation. This method was used to maintain the temperature of the growth surface. The chamber was closed properly, and vacuum was applied. Vacuum achieved was around 5.0×10⁻³ mbar. The hydrogen plasma was generated inside the chamber by igniting the plasma with microwaves. The heating temperature in the chamber was maintained in a range of 750° C.-900° C. The calibration gas having a mixture of 8% of argon per unit of hydrogen, 0.2% of oxygen per unit of hydrogen and 100 ppm of nitrogen was passed into the chamber. Methane gas in an amount of 5% per unit of hydrogen was passed inside the chamber. Carbon deposition was observed on the diamond seeds. The temperature of the growth surface of the diamond seed was maintained in between 950° C.-1050° C. The deposition was observed at a growth rate of 14 μm/hr-15 μm/hr. The deposition was carried out for 400 hours to obtain 7 carat of rough diamond from each of the seeds with an average variation of about 10% in the sizes. The color of the diamonds obtained was light brown.
The power used to generate plasma was 4.30 KW and the partial pressure of the atmosphere inside the chamber was 170 mbar.

### Example 2: Process to Produce Diamond

21 diamond seeds of 300 μm thickness were placed on molybdenum holder plate. The holder plate was kept in a chamber. A special adhesive paste described above was used to keep the seeds in place and to improve thermal conductivity from seeds to the plate. The heat transfer from the holder plate to the cooling stage was controlled by the method of thermal isolation. This method was used to maintain the temperature of the growth surface. The chamber was closed properly, and vacuum was applied. Vacuum achieved was around 5.0×10⁻³ mbar. The hydrogen plasma was generated inside the chamber by igniting the plasma with microwaves. The heating temperature in the chamber was maintained in a range of 750° C.-900° C. The calibration gas having a mixture of 5% of argon per unit of hydrogen, 0.2% of oxygen per unit of hydrogen and 50 ppm of nitrogen was passed into the chamber. Methane gas in an amount of 6% per unit of hydrogen was passed inside the chamber. Carbon deposition was observed on the diamond seeds. The temperature of the growth surface of the diamond seed was maintained in between 950° C.-1050° C. The deposition was observed at a growth rate of 11 μm/hr-12 μm/hr. The deposition was carried out for 400 hours to obtain 5 carat of rough diamond from each of the seeds with an average variation of about 10% in the sizes. The color of the diamonds obtained was lighter-brown in comparison to Example 1. The power used to generate plasma was 4.30 KW and the partial pressure of the atmosphere inside the chamber was 170 mbar.

### Example 3: Process to Produce Diamond

12 diamond seeds of 300 μm thickness were placed on molybdenum holder plate. The holder plate was kept in a chamber. A special adhesive paste described above was used to keep the seeds in place and to improve thermal conductivity from seeds to the plate. The heat transfer from the holder plate to the cooling stage was controlled by the method of thermal isolation. This method was used to maintain the temperature of the growth surface. The chamber was closed properly, and vacuum was applied. Vacuum achieved was around 5.0×10⁻³ mbar. The hydrogen plasma was generated inside the chamber by igniting the plasma with microwaves. The heating temperature in the chamber was maintained in a range of 750° C.-900° C. The calibration gas having a mixture of 4% of argon per unit of hydrogen, 0.2% of oxygen per unit of hydrogen and 250 ppm of nitrogen was passed into the chamber. Methane gas in an amount of 6% per unit of hydrogen was passed inside the chamber. Carbon deposition was observed on the diamond seeds. The temperature of the growth surface of the diamond seed was maintained in between 950 ° C.-1050 ° C. The deposition was observed at a growth rate of 17 μm/hr-19 μm/hr. The deposition was carried out for 200 hours to obtain 5.5 carat of rough diamond from each of the seeds with an average variation of about 10% in the sizes. The color of the diamonds obtained was darker brown in comparison to Example 1.
The power used to generate plasma was 4.80 KW and the partial pressure of the atmosphere inside the chamber was 175 mbar.

### Example 4: Process to Produce Diamond

12 diamond seeds of 300 μm thickness were placed on molybdenum holder plate. The holder plate was kept in a chamber. A special adhesive paste described above was used to keep the seeds in place and to improve thermal conductivity from seeds to the plate. The heat transfer from the holder plate to the cooling stage was controlled by the method of thermal isolation. This method was used to maintain the temperature of the growth surface. The chamber was closed properly, and vacuum was applied. Vacuum achieved was around 5.0×10⁻³ mbar. The hydrogen plasma was generated inside the chamber by igniting the plasma with microwaves. The heating temperature in the chamber was maintained in a range of 750° C.-900° C. The calibration gas having a mixture of 5% of argon per unit of hydrogen, 0.2% of oxygen per unit of hydrogen and 30 ppm of nitrogen was passed into the chamber. Methane gas in an amount of 6% per unit of hydrogen was passed inside the chamber. Carbon deposition was observed on the diamond seeds. The temperature of the growth surface of the diamond seed was maintained in between 950° C.-1050° C. The deposition was observed at a growth rate of 9 μm/hr-11 μm/hr. The deposition was carried out for 500 hours to obtain 9 carat of rough diamond from each of the seeds with an average variation of about 10% in the sizes. The color of the diamonds obtained was lighter brown in comparison to Example 2.
The power used was 4.90 KW and the partial pressure of the atmosphere inside the chamber was 175 mbar.

### Example 5: Process to Prepare Calibration Gas

Calibration gas was prepared by mixing argon, oxygen and nitrogen. The gases were mixed in the following proportions to obtain calibration gas:
A. 8% of argon per unit of hydrogen, 0.2% of oxygen per unit of hydrogen and 100 ppm of nitrogen.
B. 5% of argon per unit of hydrogen, 0.2% of oxygen per unit of hydrogen and 50 ppm of nitrogen.
C. 4% of argon per unit of hydrogen, 0.2% of oxygen per unit of hydrogen and 250 ppm of nitrogen.
D. 5% of argon per unit of hydrogen, 0.2% of oxygen per unit of hydrogen and 30 ppm of nitrogen.

In a process disclosed in U.S. Pat. No. 6,858,078, the method of diamond production was carried out under an atmosphere of hydrogen, 1-5% nitrogen per unit of hydrogen and 6-12% methane per unit of hydrogen. 1-3% oxygen per unit of hydrogen can be present. The growth temperature was 900-1400° C. It was found that at temperature below 1000° C., the diamond obtained was spherical, black diamond-like carbon (DLC). Temperature between 1000° C.-1100° C. produced dark brown colored diamonds.

In comparison to the above, the process of the present invention at a temperature of less than 1000° C. and in the presence of calibration gas comprising a mixture of 3% to 12% argon per unit of hydrogen, less than 1% oxygen per unit of hydrogen and less than 500 ppm nitrogen resulted in single crystal diamond with a tint of brown color. When the temperature was between 1000° C.-1100° C., single crystal diamond with a very mild tint of brown color was produced or diamond with almost no brown tint but an extremely mild yellow tint was obtained. The above examples show the color of eth diamonds produced.

When the process of the invention from each of the above example was followed at a higher temperature, undesirable results were obtained as shown below.

TABLE 1

| Sr. No. | Temperature | | Types of diamond produced |
|---|---|---|---|
| 1 | 1200-1220° | C. | Polycrystalline pyramid-like defects on the |
| | | | growth surface above 1150° C. |
| 2 | 1220-1400° | C. | Polycrystalline growth above 1200° C. |
| 3 | >1300° | C. | Polycrystalline growth above 1200° C. |

The above results in the Examples indicate that the process of the invention performed by using the calibration gas resulted in single crystal diamonds having good clarity, color and minimum or negligible defects in comparison to the conventional known process. Performing the process at higher temperatures as shown in Table 1 resulted in undesired polycrystalline diamond having defects.

The foregoing description of the invention has been set merely to illustrate the invention and is not intended to be limiting. Since modifications of the disclosed embodiments incorporating the spirit and substance of the invention may occur to a person skilled in the art, the invention should be construed to include everything within the scope of the disclosure.

1. A process for producing diamonds by microwave plasma chemical vapor deposition (MPCVD), the process comprising:
introducing a calibration gas comprising a mixture of 3% to 12% argon per unit of hydrogen, less than 1% oxygen per unit of hydrogen and less than 500 ppm nitrogen in a chamber having one or more heated diamond seeds in an atmosphere of hydrogen plasma; and
adding methane to deposit carbon on the one or more heated diamond seed.

2. The process as claimed in claim 1, wherein the one or more heated diamond seeds are placed on a holder plate in the chamber.

3. The process as claimed in claim 2, wherein the holder plate is made of molybdenum.

4. The process as claimed in claim 1, wherein the calibration gas is introduced in a vacuum applied chamber.

5. The process as claimed in claim 1, wherein the calibration gas comprises argon from 3% to 8% per unit of hydrogen and oxygen from 0.05% to 1% per unit of hydrogen and nitrogen from 5-500 ppm.

6. The process as claimed in claim 1, wherein methane is added in an amount of 2% to 7% per unit of hydrogen.

7-14. (canceled)

15. The process as claimed in claims 1, wherein the growth temperature is maintained in a range from 900° C.-1100° C.

16. The process as claimed in claim 15, wherein the vacuum is applied in the chamber with a base pressure of up to 1.0×10⁻⁵ mbar.

17. The process as claimed in claim 16, wherein the pressure in the chamber is in a range from 160 mbar to 200 mbar.

18. The process as claimed in claim 1, wherein the growth rate of diamond is 8-20 μm/hr.

19. A process for producing diamond by microwave plasma chemical vapor deposition (MPCVD), the process comprising:
placing a plurality of substrates on a holder plate in a chamber;
applying a vacuum to the chamber;
igniting a hydrogen plasma with microwaves;
heating the plurality of substrates in the chamber with the hydrogen plasma,
adding a calibration gas in the chamber containing the heated hydrogen plasma, the calibration gas comprising a mixture of 3% to 12% argon per unit of hydrogen, less than 1% oxygen per unit of hydrogen and less than 500 ppm nitrogen; and
adding methane gas in the chamber to combine with the calibration gas mixture to deposit carbon on the plurality of substrates to produce or grow diamond.

20. The process as claimed in claim 19 further including use of an adhesive, conductive comprising a colloidal solution of epoxy and gold to hold the plurality of substrates in place on the holder plate and to improve heat conductivity from the plurality of substrates to the holder plate.

21. The process as claimed in claim 20, wherein the holder plate is made of molybdenum.

22. The process as claimed in claim 19, wherein the growth temperature is maintained in a range from 900° C.-1100° C.

23. The process as claimed in claim 22, wherein the vacuum is applied in the chamber with a base pressure of up to 1.0×10⁻⁵ mbar and the pressure in the chamber is in a range from 160 mbar to 200 mbar

24. The process as claimed in claim 19, wherein methane gas is added in an amount of 2% to 7% per unit of hydrogen and the substrate is one or more diamond seed.

25. The process as claimed in claim 19, wherein the growth rate of diamond is 8-20 μm/hr.

26. The process as claimed in claim 19, wherein methane gas is added in an amount of 2% to 7% per unit of hydrogen and the substrate is one or more diamond seed.

27. A calibration gas comprising 3% to 12% argon per unit of hydrogen, less than 1% oxygen per unit of hydrogen and less than 500 ppm nitrogen.

28. The calibration gas as claimed in claim 27, wherein the calibration gas comprises said argon from 3% to 8% per unit of hydrogen, said oxygen from 0.05% to 1% per unit of hydrogen, and said nitrogen from 5-500 ppm.
